(19) United States
(12) Patent Application Publication
(10) Pub. No.: US 2023/0205937 A1
(43) Pub. Date: Jun. 29, 2023

(54) METHOD FOR DETERMINING A TOTAL LIGHT DISTRIBUTION OF A PIXEL SPOTLIGHT

(71) Applicant: dSPACE GmbH, Paderborn (DE)

(72) Inventors: Nico Rueddenklau, Liebenau (DE); Marcel Weise, Eschershausen (DE)

(21) Appl. No.: 17/996,508

(22) PCT Filed: Apr. 21, 2021
(86) PCT No.: PCT/EP2021/060336

§ 371 Date: Oct. 19, 2022

(30) Foreign Application Priority Data
Apr. 21, 2020 (DE) 10 2020 110 860.5

(51) Int. Cl. G06F 30/10

(52) U.S. Cl. CPC G06F 30/10

(57) ABSTRACT

A method for determining a total light distribution of a pixel headlamp includes: providing a texture comprising a two-dimension array having coordinates; providing a maximum energization individual light distribution for each individual light source of a plurality of individual light sources; determining a maximum energization data structure taking into account all the maximum energization individual light distributions and the texture; providing a relative energization value for each individual light source; and determining the total light distribution, taking into account the maximum energization data structure and the relative energization values of the individual light sources.

### CROSS-REFERENCE TO PRIOR APPLICATIONS

This application is a U.S. National Phase application under 35 U.S.C. § 371 of International Application No. PCT/EP2021/060336, filed on Apr. 21, 2021, and claims benefit to German Patent Application No. DE 10 2020 110 860.5, filed on Apr. 21, 2020. The International Application was published in German on Oct. 28, 2021 as WO 2021/214115 A1 under PCT Article 21(2).

### FIELD

The invention relates to a method for determining a total light distribution of a pixel headlamp via a computing unit.

Furthermore, the invention relates to a method for simulating a total light distribution of a pixel headlamp in a night journey of a virtual motor vehicle.

### BACKGROUND

In the present disclosure, pixel headlamps refer to those headlamps for the automotive sector which have a plurality of individually actuatable, individual light sources. Due to the interaction of the individual light sources, the total light distribution of the pixel headlamp is freely configurable over wide areas and can be adapted within a few milliseconds. Light-emitting diode (LED) arrays, which have a plurality of individually actuatable, individual light sources, known as pixels, are generally used as the light source. A further realization possibility is digital light processing (DLP) systems which have only one physical light source and generate the individual light sources via the actuation of micromirrors, on which the light of the light source is reflected. The light intensity of the individual light source in the pixel headlamp can be changed via the energization of the individual light source. The light intensity is greatest at maximum energization. Future generations of pixel headlamps have several thousand individual light sources, i.e., pixels.

Such pixel headlamps enable an extension of the conventional field of application of motor vehicle headlamps. They meet the technical requirement for new light functions, such as glare-free high beams, marking lights, and/or symbol projections. Glare-free high beams enable the continuous use of the high beam without the need for complete dimming in the event of oncoming traffic. Due to the individually actuatable, individual light sources, it is possible to adjust the light intensity in individual areas, such as the driver’s cab of the oncoming vehicle. Thus, in the example of using the glare-free high beam, only the driver’s cab of the oncoming vehicle can be blocked out. The illuminable region outside the driver’s cab can continue to be illuminated. As a result, safety during night journeys is significantly increased, and manual dimming up and down is no longer needed.

In order to be able to implement such light functions in a controlled manner, precise control of each individual light source is advantageous, e.g., depending upon the driving situation, the state of the driver’s own vehicle, the influences from the environment, and the previously used energization values of the individual light source. In order to integrate such light functions of the pixel headlamps into road traffic, a large number of complex pre-calculations and careful programming of a control software for the pixel headlamps are required in order to ensure reliable functioning of the system. Particularly in the case of the function of the glare-free high beam, the actual events occurring are continuously detected and correctly assessed, in order to be able to reliably control the individual pixels thereupon. Particularly in the case of the glare-free high beam, a faulty control of the pixels represents a great risk of traffic accidents. Therefore, due to the risk, real night journeys are carried out in advance, in order to subsequently use them as the basis for calculating the total light distribution. However, real night journeys are not only dangerous, but are furthermore also time-consuming as well as expensive. However, these disadvantages can be avoided via night journey simulations.

In a night journey simulation, the total light distribution of the pixel headlamp is calculated multiple times in succession, according to the simulation specifications of the night journey. The calculation of the total light distribution of the pixel headlamp should therefore take place very quickly, so that high clock rates of the calculation are possible, in order to enable the real-time requirement of the simulation.

Specifically, for example, the simulation environment, “LucidDrive,” from the software package, “LucidShape,” from the company Synopsys enables the simulation of pixel headlamps in which a light distribution of the pixel headlamp is simulated. However, the number of individual light sources in the simulation is limited to 126 in the case of a physically-motivated simulation. If pixel headlamps having more individual light sources are to be simulated, via the simulation environment using the “AFS Masking Pixel Light Feature,” only the constant total light distribution of all the individual light sources that have been fully energized can be rendered, from which regions could be blocked out. However, account is not taken of whether the blocking out by the pixel headlamp can be realized at all. The disadvantage of this simulation environment in one case is that the simulation is not physically motivated in the case of a high number of individual light sources, i.e., takes place independently of the conditions of the pixel headlamp, and thus without taking into account an achievable headlamp-specific implementation.

Other conventional simulation environments, such as the “LightDriver,” used by the company, “HELLA KGaA,” from the software package, “HE LIOS,” support only pixel headlamps having up to 100 individual light sources.

In conventional methods for determining total light distributions of pixel headlamps, computing time increases significantly with the number of individual light sources, such that these conventional methods are not suitable for performing simulations, since real-time requirements are no longer able to be maintained in the case of a few hundred individual light sources.

### SUMMARY

In an exemplary embodiment, the present invention provides a method for determining a total light distribution of a pixel headlamp via a computing unit. The pixel headlamp comprises a plurality of individual light sources, and a light intensity of a respective individual light source can be influenced by energization of the respective individual light source. The method includes the steps of: a) providing a texture on the computing unit comprising a two-dimension array having coordinates; b) providing a maximum energization individual light distribution for each individual light source on the computing unit, wherein the maximum energization individual light distribution represents at least the light intensity of the individual light source per coordinate at maximum energization of the individual light source; c) determining a maximum energization data structure taking into account all the maximum energization individual light distributions and the texture, wherein the maximum energization data structure comprises a target coordinates list having target coordinates entries, one light intensity list per target coordinates entry having at least one light intensity entry, and one individual light source identification list per target coordinates entry having at least one identification entry, and wherein the maximum energization data structure at least represents which individual light sources influence the light intensity per coordinate of the texture, and to what extent, at maximum energization; d) providing a relative energization value for each individual light source on the computing unit, wherein the relative energization value represents the energization of the individual light source; and e) determining the total light distribution, taking into account the maximum energization data structure and the relative energization values of the individual light sources.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a flowchart having the sequence of a method for determining a total light distribution of a pixel headlamp via a computing unit, according to a preferred embodiment of the invention;

FIG. 2 schematically shows a maximum energization data structure which is used in the method for determining a total light distribution of a pixel headlamp, according to a preferred embodiment of the invention;

FIG. 3 shows a further schematic representation of the maximum energization data structure from FIG. 2; and

FIG. 4 schematically shows a target coordinates buffer, a light intensity buffer, and an individual light source identification buffer, which are used in the method for determining a total light distribution of a pixel headlamp, according to a preferred embodiment of the invention.

### DETAILED DESCRIPTION

Exemplary embodiments of the invention provide a method for determining a total light distribution of a pixel headlamp via a computing unit, which is particularly fast even in the case of a number of individual light sources. Furthermore, exemplary embodiments of the invention provide a method for simulating a total light distribution of a pixel headlamp in a night journey of a virtual motor vehicle that meets the real-time requirement.

According to the invention, a method for determining a total light distribution of a pixel headlamp is thus provided via a computing unit, wherein the pixel headlamp comprises a plurality of individual light sources, and wherein it is possible for a light intensity of the individual light source to be influenced by energization of the individual light source, comprising the steps of:
a) providing a texture on the computing unit comprising a two-dimensional array with coordinates,
b) providing a maximum energization individual light distribution for each individual light source on the computing unit, wherein the maximum energization individual light distribution represents at least the light intensity of the individual light source per coordinate at maximum energization of the individual light source,
c) determining a maximum energization data structure taking into account all of the maximum energization individual light distributions and the texture, wherein the maximum energization data structure comprises a target coordinates list having target coordinates entries, one light intensity list per target coordinates entry having at least one light intensity entry, and one individual light source identification list per target coordinates entry having at least one identification entry, and wherein the maximum energization data structure represents at least which individual light sources influence the light intensity per coordinate of the texture, and to what extent, at maximum energization,
d) providing a relative energization value for each individual light source on the computing unit, wherein the relative energization value represents the energization of the individual light source, and
e) determining the total light distribution, taking into account the maximum energization data structure and the relative energization values of the individual light sources.

In an exemplary embodiment, the method converts the maximum energization individual light distribution provided into the maximum energization data structure, which allows a particularly effective determination of the total light distribution. In other words, the maximum energization individual light distributions are initially preprocessed. Only after this preprocessing is carried out, and the maximum energization data structure is present, is the total light distribution of the individual light sources averaged, taking into account the relative energization values of the individual light sources.

In principle, the total light distribution of the pixel headlamp can be described as a linear combination of all individual light distributions of the individual light sources, wherein the matrices Mᵢ denote, in the following, the maximum energization individual light distributions, and cᵢ in each case is the relative energization value of the respective individual light source. The total light distribution M_{G} results if, for the sake of simplicity, it is assumed that all individual light distributions and the total light distribution are present over the same solid angle region:

$${M}_{G} = {\sum }_{i} {c}_{i} ⋅ {M}_{i}$$

In the case of pixel headlamps, the number of individual light sources is very high, such that the calculation of the sum requires a lot of computing time in the prior art. Furthermore, the individual light sources of a pixel headlamp generally radiate onto only locally limited regions, such that the matrices Mᵢ are sparsely populated matrices, i.e., many of their entries are zero. Thus, when solving the above sum according to conventional methods, a large amount of computing time is used to add zeros, which is less efficient.

In a first step, a method according to the invention provides the texture, on the computing unit, in which the total light distribution to be determined is written. The texture comprises the two-dimensional array, wherein the row and column numbers of the two-dimensional array define the coordinates. The texture and the number of coordinates, i.e., a number of discretization points in both dimensions, influence in which spatial region and at which resolution the total light distribution is determined. In the case of many coordinates in a spatial region, the total light distribution is very fine-grained, i.e., determined at high resolution. It is preferably provided for the texture to be provided in a spherical coordinate system with azimuth and polar angles. The coordinates are therefore preferably solid angles.

In a further step of the method, the maximum energization individual light distribution for each individual light source is provided on the computing unit. The maximum energization individual light distribution represents at least the light intensity of the individual light source per coordinate at a maximum energization of the individual light source. Preferably, therefore, the maximum energization individual light distribution represents the light intensity of the individual light source in a defined solid angle region at maximum energization of the individual light source.

The texture and the maximum energization individual light distribution may be provided to the computing unit independently of one another. Alternatively, it can be provided for the texture and the coordinates to be produced from the maximum energization individual light distributions provided. It is further preferably provided for the total light distribution to be determined at the same resolution as the resolution of the maximum energization individual light distributions provided.

In a further step, the maximum energization data structure is determined taking into account all the maximum energization individual light distributions and the coordinates list. The maximum energization data structure, also referred to below as a data structure, comprises the target coordinates list with the target coordinates entries, in each case one light intensity list per target coordinates entry, and in each case one individual light source identification list per target coordinates entry. This is therefore a multidimensional data structure having interleaved lists. The data structure comprises the information as to which individual light sources influence the light intensity per coordinate of the texture, and to what extent, at maximum energization.

In other words, the data structure represents which and how many individual light sources radiate, and how strongly, onto a coordinate of the texture.

In a further step of the method, the relative energization values for each individual light source are provided on the computing unit. The relative energization value is preferably normalized to the value range 0 to 1. The relative energization value represents the energization of the individual light source. In other words, the relative energization value reflects a global light intensity of the individual light source. If, for example, the relative energization value is 1 or 100%, then the individual light source has an individual light distribution corresponding to the maximum energization individual light distribution. If the energization value is, for example, 0.5 or 50%, the individual light source has an individual light distribution which corresponds, in each direction, to half of the maximum energization individual light distribution. In other words, the individual light distribution is scaled globally by the energization value.

The maximum energization data structure has, with the target coordinates list, the light intensity lists, and the individual light source identification lists, a structure which is tailored to the architecture of the computing unit, which, in a further step of the method, determines the total light distribution, taking into account the relative current feed values. Thus, the determination of the total light distribution is very fast. Instead of, as hitherto, determining the total light distribution via an iterative method, in which a computing cycle must be repeated as often as there are maximum energization individual light distributions, the data structure makes it possible to determine the total light distribution with one cycle. In other words, the method, by the preprocessing of the maximum energization individual light distribution, makes it possible for the method step in which the total light distribution is determined to be particularly fast. Since, in the case of a simulation in which the total light distribution of a pixel headlamp is determined several times in succession, with different energization values, the preprocessing of the maximum energization individual light distribution must be performed only at the beginning, and, thereafter, only the relative energization values are updated according to the simulation specifications, the method is therefore particularly suitable for real-time-capable simulations in which the total light distribution of the pixel headlamp is determined at a high clock frequency.

The maximum energization data structure also has the advantage that its size does not necessarily increase with the number of individual light sources of the pixel headlamp or with the number of maximum energization individual light distributions. Instead, the size of the data structure is determined, inter alia, by a number of overlapping regions of the maximum energization individual light distributions. Overlapping regions are preferably understood to mean the coordinate region of the texture that is irradiated by more than one individual light source. The size of the overlapping regions generally does not increase with the increasing number of individual light sources. Thus, the method according to an embodiment of the invention is very quick when determining the total light distribution of pixel headlamps comprising a very high number of individual lights, the maximum energization individual light distributions of which are in each case distinguished sharply from one another and in each case irradiate only one segmented coordinate region of the texture.

According to a further exemplary embodiment of the invention, the step c) additionally comprises the following steps:
c1) creating the target coordinates list without target coordinates entries,
c2) successive processing of all the maximum energization individual light distribution, taking into account all coordinates of the texture, comprising the following steps:
c2.1) determining the light intensity of the maximum energization individual light distribution on a coordinate of the texture,
c2.2) checking whether the target coordinates list has a target coordinates entry at the coordinate of the texture,
c2.3) in the case of the target coordinates list not having a target coordinates entry at the coordinate, creating the target coordinates entry by adding the coordinate as the target coordinate to the target coordinates list, and applying the light intensity list and the individual light source identifier list for the corresponding target coordinates entry, wherein the light intensity list comprises the light intensity entry which represents the light intensity of the individual light source on the coordinate of the texture, and the individual light source identification list comprises the identification entry that identifies the individual light source,
c2.4) in the case of the target coordinates list having a target coordinates entry at the coordinate, adding a further light intensity entry to the light intensity list and a further identification entry to the individual light source identification list.

The method therefore preferably provides for the maximum energization data structure to be created via an iterative process. In particular, it is provided that there be two interconnected iteration processes, wherein iteration over all the maximum energization individual light distribution is performed in the superordinate iteration process, and iteration over all coordinates of the texture is performed in the subordinate iteration process. In other words, re-sorting takes place, compared with the manner in which the information of the light intensity is sorted in the maximum energization individual light distribution, for the purpose of sorting the information in the maximum energization data structure having the interconnected lists.

In order to further reduce the computing time for determining the total light distribution, a further exemplary embodiment of the invention provides that, in step c), a maximum energization data structure be provided which, in the light intensity list, exclusively comprises light intensity entries which exceed a preselected threshold light intensity, and the corresponding individual light source identification lists exclusively comprise identification entries of individual light sources whose light intensity entries exceed the preselected threshold light intensity. In other words, light intensities of the maximum energization individual light distribution on coordinates of the coordinates list that falls below the preselected threshold light intensity are rejected. Thus, low light intensities of the maximum energization individual light distribution, which are too dark to have an influence on the total light distribution, are not even taken into account. The size of the maximum energization data structure is thus reduced, and the computing time is accelerated.

The above-described iterative process as to how the maximum energization data structure is created makes it possible, in a simple manner, to provide the preferably provided maximum energization data structure, in which the light intensity list of the maximum energization data structure exclusively comprises light intensity entries that exceed the preselected threshold light intensity, and the corresponding individual light source identification lists exclusively comprise identification entries of individual light sources whose light intensity entries exceed the preselected threshold light intensity. For this purpose, according to a further exemplary embodiment of the invention, it is provided that, after step c2.1), the method additionally comprises the step of:

c2.1) determining whether the light intensity of the maximum energization individual light distribution on the coordinate exceeds the preselected threshold light intensity, and wherein the method performs steps c2.2) through c2.4) for this coordinate only if the threshold light intensity is exceeded.

In connection with the acceleration of the computing time, according to a further exemplary embodiment of the invention, it is provided that the method additionally comprises step b2) of determining a compressed maximum energization individual light distribution from the maximum energization individual light distribution, wherein the compressed maximum energization individual light distribution represents at least the light intensity of the individual light source in that coordinate region which is irradiated by the individual light source at maximum energization in such a way that the light intensity exceeds a further preselected threshold light intensity or a threshold light intensity based upon a preselected percentage threshold value, and wherein, in step c), the maximum energization data structure is determined taking into account all the compressed maximum energization individual light distributions. The method thus preferably provides that computing time be saved by using particular properties of the maximum energization individual light distributions. As already mentioned, the maximum energization individual light distribution represents the light intensity of one individual light source per coordinate. Due to the locally limited irradiation of an individual light source, each individual light source radiates only into a small coordinate region, so that many coordinates of the texture have no, or only a very low, light intensity, due to the individual light source.

Preferably, the method provides that this effectively illuminated coordinate region, i.e., the region of the texture which is irradiated by the individual light source at maximum excitation, in such a way that the luminous intensity exceeds the further preselected threshold value light intensity, be determined via the edge detection algorithm and only this effectively illuminated coordinate region of the maximum current light distributions, i.e., the compressed maximum current light distributions, be further used. The edge detection algorithm preferably comprises performing a low-pass filtering, and, more preferably, performing a low-pass filtering via a Gaussian filter. Thus, the amount of data is reduced, such that the downstream step c) takes less time.

As an alternative to the edge detection algorithm, a further exemplary embodiment of the invention provides that the determination of the compressed maximum energization individual light distribution comprises determining an effectively illuminated, rectangular coordinate region. Further preferably, the effectively illuminated, rectangular coordinate region is determined in which, in a first step, a scattered light-reduced maximum energization individual light distribution is provided, by reducing a scattered light component in the maximum energization individual light distribution. This is preferably done by low-pass filtering. In a second step, a maximum light intensity and a coordinate having the maximum light intensity in the scattered light-reduced maximum energization individual light distribution are determined, in a third step, the threshold light intensity is determined, taking into account the maximum light intensity and the preselected percentage threshold value, and, in a fourth step, the effectively illuminated, rectangular coordinate region is determined, taking into account the scattered light-reduced maximum energization individual light distribution, the coordinate having the maximum light intensity and the threshold light intensity. It is preferably provided that, in the fourth step, the effectively illuminated, rectangular coordinate region be determined, in which a rectangle, which initially comprises exclusively the coordinate having the maximum light intensity, is enlarged in this way, until the rectangle comprises all coordinates having light intensity values which lie above the threshold light intensity. It is further preferably provided that the effectively illuminated, rectangular coordinate region correspond to the compressed maximum energization individual light distribution. In other words, data points of the maximum energization individual light distribution, which are located outside the effectively illuminated, rectangular coordinate region, are not further taken into account for the compressed maximum energization individual light distribution.

As already mentioned, the data structure having the target coordinates list, the light intensity lists, and the individual light source identification lists has a structure that is tailored to the architecture of the computing unit. In this context, according to a further exemplary embodiment of the invention, it is provided that the method, after step d), additionally comprises the following steps:
d1) generating a target coordinate buffer from the target coordinates list, a light intensity buffer from all the light intensity lists, and an individual light source identification buffer from all the individual light source identification lists of the data structure, wherein the target coordinate buffer contains a number of ZK elements corresponding to the number of target coordinates entries of the target coordinates list, and the target coordinate buffer comprises a start point and a length specification for each ZK element.
d2) storing the target coordinate buffer, the light intensity buffer, and the individual light source identification buffer on the computing unit.

The method therefore preferably provides, in a further step, for three buffers to be created from the data structure, which buffers are stored on the computing unit. Buffer is preferably understood to be a memory for the intermediate storage of the data, which has a form that is quickly readable for the computing unit. Particularly preferably, a buffer is understood to mean a cohesive memory region or memory block of a predetermined data type, wherein the buffer contains a configurable number of elements, and it is possible to draw upon any desired element per index. Further preferably, the target coordinates buffer, the light intensity buffer, and the individual light source identification buffer are applied and/or stored on a graphics card of the computing unit.

The target coordinates buffer, the light intensity buffer, and the individual light source identification buffer have the same data as the lists of the data structure, but the buffers are structured such that the data are present in the memory in continuous form. It is preferably provided for the ZK elements of the target coordinates buffer to correspond to the target coordinates entries of the target coordinates list, wherein the target coordinates buffer comprises a starting point (buffer offset) and a length specification (buffer count) for each ZK element. The starting point and the length specification each refer to a location in the light intensity buffer and in the individual light source identification buffer, where the light intensity entries and individual light source identification entries stored for this target coordinate are stored. Preferably, the starting point indicates an index in the respective buffer, and the length specification indicates the length of the region.

According to a further exemplary embodiment of the invention, it is provided for the step e), i.e., the determination of the total light distribution, to be carried out taking into account the maximum energization data structure and the relative energization values of the individual light sources, via a graphics card of the computing unit. This has the advantage that the determination, via the high parallelizability, is particularly fast. Preferably, the target coordinates buffer, the light intensity buffer, and the individual light source identification buffers are adjusted, in their structure, to the calculation via the graphics card.

In this context, according to a further exemplary embodiment of the invention, it is provided for the step e) to comprise the following steps:
e1) generating the target coordinates buffer from the target coordinates list, the light intensity buffer from all the light intensity lists, and the individual light source identification buffer from all the individual light source identification lists of the maximum energization data structure, wherein the target coordinates buffer contains the number of ZK elements corresponding to the number of target coordinates entries of the target coordinates list, and the target coordinates buffer comprises a starting point and a length specification for each of ZK element, or
e1′) loading the stored target coordinates buffer, the stored light intensity buffer, and the stored individual light source identification buffer on the computing unit, and
e2) transmitting the target coordinates buffer, the light intensity buffer, and the individual light source identification buffer to a graphics card of the computing unit,
e3) generating an energization value buffer from the provided relative energization values for each individual light source,
e4) transmitting the energization value buffer to the graphics card of the computing unit, and
e5) determining the total light distribution via the graphics card of the computing unit, taking account of the target coordinates buffer, the light intensity buffer, the individual light source identification buffer, and the energization value buffer.

According to a further exemplary embodiment of the invention, in step e5), a computer shader having shader units is used, wherein each shader unit is processed in isolation, and/or execution strings of the computer shader run in parallel on several shader units of the graphics card. A computer shader is understood here to mean a programmable computing unit of the graphics card. Preferably, as many execution strings of the computer shader are executed as there are ZK elements in the target coordinates buffer. Due to the high number of shader units, which are available on modern graphics processors of the graphics cards, it is preferably provided for many of the execution strings (threads) to run in parallel. The execution strings are preferably distinguished from one another by an ID. Preferably, the ID ensures that each execution string processes exclusively one of the target coordinates. This results in a high degree of parallelization.

In particular, the ID of the execution string is used as an index for reading out the target coordinates buffer. In addition, the coordinate of the target texture at which the execution string determines the light intensity is obtained. In addition, the starting point and the length specification in the target coordinates buffer indicate the indices at which the light intensity buffer and the individual light source identification buffer are read out.

According to a further exemplary embodiment, the method comprises, for each ZK element in the target coordinates buffer, the step of scaling the light intensity entry in the light intensity buffer with the energization entry in the energization buffer, wherein the starting point and the length specification in the target coordinate buffer indicate the indices in the light intensity buffer and the energization buffer at which the light intensity entry and the energization entry are located, and subsequent summation. After all the execution strings have completed their execution, the light intensity for all target coordinates, and thus the total light distribution, is determined.

Unlike in the case of conventional methods, in which the individual light distributions are added to the texture through several iterations, the method has the advantage that the determination of the total light distribution is possible via a single computer-shader cycle. The organization of the execution strings according to target coordinates creates implicit execution security of the execution strings. Write conflicts between the execution strings are excluded, since each execution string exerts exclusive write access on a unique target coordinate. All other data are accessed exclusively for reading. The method has the advantage that the graphics processor is used very efficiently, because, for each execution string, the data are present in the buffer in a cohesive manner, which accelerates the reading of the data from the buffer. In addition, the implicit execution security renders it unnecessary to explicitly provide conflict-resolving structures such as atomic operations or synchronizations within execution strings. Due to the lack of conflict-resolving structures, the total light distribution can be determined particularly quickly.

According to a further exemplary embodiment of the method, it is provided that the maximum energization individual light distribution provided in step b) represents, in addition to the light intensity of the individual light source per coordinate, an item of color information of the individual light source per coordinate, and the light intensity list of the maximum energization data structure comprises a combined light intensity-color information entry. Preferably, the light intensity-color information entry comprises XYZ coordinates in the CIE color space. In this case, Y corresponds to the light intensity, and X and Z specify the color information. The method preferably comprises the step of converting the XYZ coordinates of the light intensity-color information entry in the CIE color space into RGB coordinates of the RGB color space. The representation of the light intensity-color information entry in the RGB color space has the advantage that a simple reproduction is possible, via common technical output devices.

Furthermore, the invention relates to a method for simulating a total light distribution of a pixel headlamp in a night journey of a virtual motor vehicle, comprising the steps of:
one-time performance of steps a) through c) of the method for determining a total light distribution of a pixel headlamp via a computing unit and
repeated, successive performance of steps d) and e) of the method for determining the total light distribution of a pixel headlamp via a computing unit, or
one-time performance of steps a) through c) of the method for determining a total light distribution of a pixel headlamp via a computing unit,
one-time performance of the following steps e1) or e1′) and e2) of the method for determining a total light distribution of a pixel headlamp, and
repeated, successive performance of steps e3) through e5) of the method for determining a total light distribution of a pixel headlamp.

The simulation of the total light distribution of the pixel headlamp in the night journey of the virtual motor vehicle preferably comprises the determination of successive total light distributions of the pixel headlamp at a frequency corresponding to a control frequency of a real controller of a pixel headlamp. The control frequencies of the real controllers of pixel headlamps are generally in the range of 50 Hz. The frequency at which the successive total light distributions of the pixel headlamp are determined preferably corresponds to 30 to 60 Hz, and particularly preferably 50 Hz. It is preferably provided for the virtual motor vehicle to comprise at least the pixel headlamp for which the total light distribution is determined.

According to a further exemplary embodiment of the method, it is provided for the pixel headlamp to comprise more than 200 individual light sources. Due to the rapid determination of the total light distribution, real-time simulations of pixel headlamps having a high number of individual light sources can also be carried out via the method.

The invention is explained in more detail below on the basis of a preferred embodiment of the invention, with reference to the drawings.

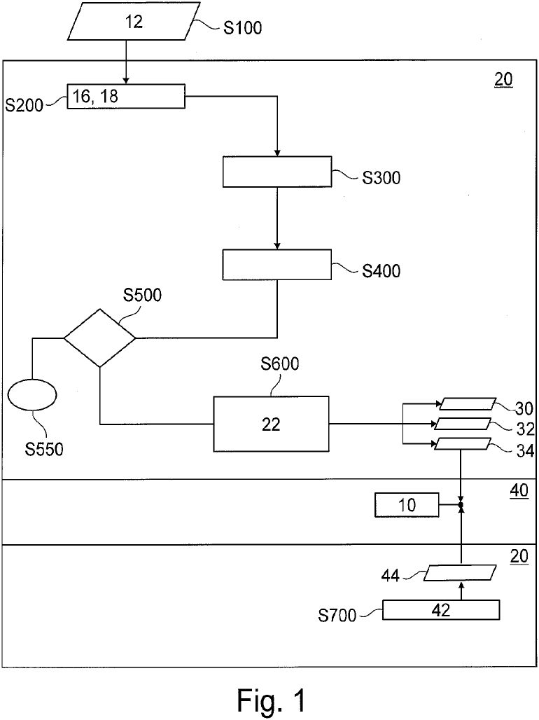

FIG. 1 schematically shows a flowchart having the sequence of a method for determining a total light distribution 10 of a pixel headlamp via a computing unit 20 according to a preferred embodiment of the invention.

The steps of the method will be explained below with reference to FIGS. 1 through 4. The method comprises several steps, wherein measurement data 12 of a pixel headlamp comprising several individual light sources is provided in a first step S100. A light intensity of the individual light source of the pixel headlamp can be changed via energization of the individual light source. The measurement data 12 comprise a two-dimensional coordinates list having coordinates 14, hereafter referred to as texture 16 and shown in FIG. 3, as well as a maximum energization individual light distribution 18 for each individual light source of the pixel headlamp, which is likewise depicted schematically in FIG. 3, wherein the maximum energization individual light distribution 18 represents at least the light intensity of the individual light source per coordinate 14, at maximum energization of the individual light source. In the present disclosure, the maximum energization individual light distribution 18 is provided in polar coordinates which specify the light intensity of the individual light source per solid angle.

In a further step S200 of the method, the measurement data 12 are read into the computing unit 20, and the initially empty texture 16 and the maximum energization individual light distributions 18 are thus provided to the computing unit 20.

In a further step S300, the maximum energization individual light distributions 18 are initially preprocessed and converted into compressed maximum energization individual light distributions. For this purpose, the size of a solid angle region irradiated by the individual light source is determined. This solid angle region is stored in the form of angular intervals of the polar and azimuth angles per maximum energization individual light distribution. Thus, the data amount is reduced such that the subsequent steps take less time. The solid angle region is determined either by an edge detection algorithm or by an effectively illuminated, rectangular coordinate region being determined.

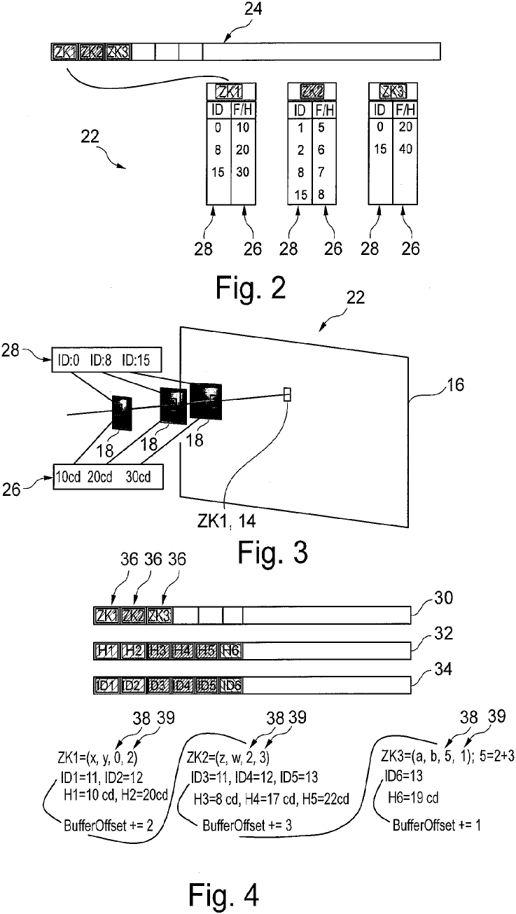

The goal of the subsequent steps S400 through S600 is to provide a maximum energization data structure 22. The maximum energization data structure 22 is shown schematically in FIGS. 2 and 3 and comprises a target coordinates list 24 having target coordinates entries ZK, a light intensity list 26 per target coordinates entry ZK having at least one light intensity entry, and one individual light source identification list 28 per target coordinates entry ZK having at least one identification entry. In the present disclosure, the maximum energization data structure 22 shows which individual light sources influence the light intensity per coordinate 14 of the texture 16, and to what extent, at maximum energization. FIG. 2 shows the light intensity list 26 and the individual light source identification list 28 for three target coordinates entries ZK of the target coordinates list 24. FIG. 3 shows the texture 16, wherein the maximum energization individual light distribution 18 is shown schematically, and the composition of said target coordinate is shown, for a coordinate 14, i.e., the target coordinate, which corresponds to the target coordinates entry ZK1 in FIG. 2.

In order to create the maximum energization data structure 22, the method performs steps S400 through S600. In step S400, an empty target coordinates list 24 is provided, which is then successively filled with target coordinates entries ZK, and the corresponding light intensity lists 26 and individual light source identification lists 28 are created. In this case, an interconnected iteration process takes place, wherein iteration is performed over all maximum energization individual light distributions 18 in a superordinate iteration process, and iteration is performed over all the coordinates 14 of the texture 16 in a subordinate iteration process.

For a maximum energization individual light distribution 18, the solid angles are first converted into the corresponding coordinates 14 of the texture 16. In the present disclosure, both the coordinates 16 of the texture 14 and the maximum energization individual light distribution 18 are present in spherical coordinates. In a further step S500, it is determined whether the light intensity of the maximum energization individual light distribution 18 on the coordinate 14 exceeds a preselected threshold light intensity.

If the light intensity is smaller than the preselected threshold light intensity, this coordinate 14 is rejected, as schematically illustrated in step S550, and not taken into account in the maximum energization individual light distribution 22.

If the light intensity is greater than the preselected threshold light intensity, a check is made as to whether the target coordinates list 24 has a target coordinates entry ZK at the coordinate 14 of the texture 16.

In the event that the target coordinates list 24 does not have a target coordinates entry ZK at the coordinate 16, the target coordinates entry ZK is created by adding the coordinate 14 as the target coordinate to the target coordinates list 24, and the light intensity list 26 and the individual light source identification list 28 are created for the corresponding target coordinates entry ZK.

In the event that the target coordinates list 24 has a target coordinates entry ZK at the coordinate 14, a further light intensity entry is added to the light intensity list 26, and a further identification entry is added to the individual light source identification list 28.

After the interconnected iteration process has been completed, the maximum energization data structure 22 is determined. In a further step of the method, three computer buffers 30, 32, 34 are created from the maximum energization data structure 22.

Specifically, a target coordinates buffer 30 is created from the target coordinates list 24, a light intensity buffer 32 is created from all the light intensity lists 26, and an individual light source identification buffer 34 is created from all the individual light source identification lists 28. The computer buffers 30, 32, 34 are shown schematically in FIG. 4. The target coordinates buffer 30 contains a number of ZK elements 36, which corresponds to the number of target coordinates entries ZK of the target coordinates list 24 and comprises, for each ZK element, a starting point 38, referred to as buffer offset, and a length specification 39 of what is known as the buffer count. FIG. 4 shows, on the basis of three ZK elements, viz., ZK1, ZK2, and ZK3, how the data are applied in the respective computer buffers 30, 32, 34. In this case, the ZK element ZK2 corresponds to the target coordinate in FIG. 3, since it is influenced by three maximum energization individual light distributions 18. ZK1 is composed of two maximum energization individual light distributions 18, ZK2 from three, and ZK3 from one maximum energization individual light distribution 18.

In the present preferred exemplary embodiment here, the method provides that the created computer buffers 30, 32, 34 be stored on the computing unit 20.

In a further step S700 of the method, relative energization values 42 for each individual light source are provided on the computing unit 20, wherein the relative energization value 42 represents the energization of the individual light source.

In order to determine the total light distribution 10, in a further step of the method, the computer buffers 30, 32, 34 are transferred into a fast memory of a graphics processor, GPU, of a graphics card 40. Furthermore, an energization value buffer 44 is created from the relative energization values 42 provided on the computing unit 20, which buffer is likewise transmitted to the graphics card 40. In order to determine the total light distribution via the graphics map 40, taking into account the target coordinates buffer 30, the light intensity buffer 32, the individual light source identification buffer 34, and the energization value buffer 44, a computer shader is used in the present embodiment.

In the following, the logical sequence of the computer shader is described, which must be performed when determining the total light distribution. In the case of a simulation in which the total light distribution is determined in succession in a sequence of frames, the logical sequence is thus completed in each frame. The program code of the computer-shader is executed as often as there are ZK elements 36 in the target coordinates buffer 30. Due to the several thousand cores available in modern GPU’s, many of the execution strings (threads) run in parallel. The threads are distinguished by a thread ID, whereby they are continuously numbered. The thread ID is used in order that each thread process a single ZK element, and thus in each case determine the light intensity for a target coordinate. This results in a high degree of parallelization.

In detail, the thread ID of the thread is used as an index for reading out the target coordinates buffer 30, referred to hereafter as ZK buffer. This encodes the coordinate 14 of the texture 16 at which the currently considered thread needs to determine the light intensity. In addition, the starting point 38 (buffer offset) and the length specification 39 (buffer count) specify the indices at which the light intensity buffer 32, referred to in the following as light intensity buffer, and the individual light source identification buffer 34, referred to hereafter as ID buffer, are read out. In order to determine the total light distribution, the respective values of the light intensity buffer 32 are scaled and subsequently summed with the corresponding values, referred to hereafter as energization, of the energization value buffer 44, referred to hereafter as the energization value buffer. In this case, the entries of the individual light source identification buffer 34 represent the indices at which the energization value buffer 44 has to be read out. The following operations are carried out for the respective thread ID transferred to the kernel or thread:

Initial:
ID = thread ID (continuous integer beginning at 0 for identification of each thread)
Light intensity sum = 0 (auxiliary variable)
Light intensity value = 0 (auxiliary variable)
Energization = 0 (auxiliary variable)
ELV_ID = 0 (auxiliary variable)
ZK = ZK-Buffer[ID].xy (data type unit 4 contains four components: x, y, z, w)
StartOffset = ZK-Buffer[ID].z
NumELV = ZK-Buffer[ID].w
EndOffset = StartOffset + NumELV
Loop:
Loop condition: For i = StartOffset to EndOffset
Loop operations:
   ELV_ID = ID-Buffer[i]
   light intensity value = light intensity buffer[i]
   energization = energization values buffer[ELV_ID]
   light intensity sum = light intensity sum + energization * light intensity value Loop end
Return:
Texture[ZK] = light intensity sum

After all threads have completed their execution, the light intensity of the total light distribution is determined. The texture 16 thus obtained can now be used to render the headlamp light of the pixel headlamp in a scene.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

List of reference signs

| | |
|---|---|
| 10 | total light distribution |
| 12 | measurement data |
| 14 | coordinates |
| 16 | texture |
| 18 | maximum energization individual light distribution |
| 20 | computing unit |
| 22 | maximum energization data structure |
| 24 | target coordinates list |
| ZK | target coordinates entry |
| 26 | light intensity list |
| 28 | individual light source identification list |
| 30 | target coordinates buffer |
| 32 | light intensity buffer |
| 34 | individual light source identification buffer |
| 36 | ZK element |
| 38 | starting point |
| 39 | length specification |
| 40 | graphics card |
| 42 | relative energization value |
| 44 | energization value buffer |

1. A method for determining a total light distribution of a pixel headlamp via a computing unit, wherein the pixel headlamp comprises a plurality of individual light sources, and wherein a light intensity of a respective individual light source can be influenced by energization of the respective individual light source, comprising the steps of:
a) providing a texture on the computing unit comprising a two-dimension array having coordinates;
b) providing a maximum energization individual light distribution for each individual light source on the computing unit, wherein the maximum energization individual light distribution represents at least the light intensity of the individual light source per coordinate at maximum energization of the individual light source;
c) determining a maximum energization data structure taking into account all the maximum energization individual light distributions and the texture, wherein the maximum energization data structure comprises a target coordinates list having target coordinates entries, one light intensity list per target coordinates entry having at least one light intensity entry, and one individual light source identification list per target coordinates entry having at least one identification entry, and wherein the maximum energization data structure at least represents which individual light sources influence the light intensity per coordinate of the texture, and to what extent, at maximum energization;
d) providing a relative energization value for each individual light source on the computing unit, wherein the relative energization value represents the energization of the individual light source; and
e) determining the total light distribution, taking into account the maximum energization data structure and the relative energization values of the individual light sources.

2. The method according to claim 1, wherein step c) comprises the following steps:
c1) creating the target coordinates list without target coordinates entries; and
c2) successive processing of all maximum energization individual light distributions, taking into account all coordinates of the texture, comprising:
c2.1) determining the light intensity of the maximum energization individual light distribution on a coordinate of the texture;
c2.2) checking whether the target coordinates list has a target coordinates entry at the coordinate of the texture; and
performing one of the following: c2.3) in the case of the target coordinates list not having a target coordinates entry at the coordinate, creating the target coordinates entry by adding the coordinate as the target coordinate to the target coordinates list and applying the light intensity list and the individual light source identification list for the corresponding target coordinates entry, wherein the light intensity list comprises the light intensity entry representing the light intensity of the individual light source on the coordinate of the texture, and the individual light source identification list comprises the identification entry identifying the individual light source; or c2.4) in the case of the target coordinates list having a target coordinates entry at the coordinate, adding a further light intensity entry to the light intensity list, and a further identification entry to the individual light source identification list.

3. The method according to claim 1, wherein, in step c), a maximum energization data structure is provided, which, in the light intensity list, exclusively comprises light intensity entries which exceed a preselected threshold light intensity, and the corresponding individual light source identification lists exclusively comprise identification entries of individual light sources whose light intensity entries exceed the preselected threshold light intensity.

4. The method according to claim 2, wherein the method additionally comprises, after step c2.1), the following step:
determining whether the light intensity of the maximum energization individual light distribution on the coordinate exceeds the preselected threshold intensity, and performing steps c2.2) through c2.4) for this coordinate based on the threshold light intensity being exceeded.

5. The method according to claim 1, wherein the method additionally comprises step b2) of determining a compressed maximum energization individual light distribution from the maximum energization individual light distribution;
wherein the compressed maximum energization individual light distribution represents at least the light intensity of the individual light source in the coordinate region that is irradiated by the individual light source at maximum energization in such a way that the light intensity exceeds a further preselected threshold light intensity or a threshold light intensity based upon a preselected percentage threshold value, and wherein, in step c), the maximum energization data structure is determined taking into account all the compressed maximum energization individual light distributions.

6. The method according to claim 5, wherein the compressed maximum energization individual light distribution is determined by means of an edge detection algorithm; or
wherein the determination of the compressed maximum energization individual light distribution comprises determining an effectively illuminated, rectangular coordinate region by the following steps:
providing a scattered light-reduced maximum energization individual light distribution by reducing a scattered light component in the maximum energization individual light distribution;
determining a maximum light intensity and a coordinate having the maximum light intensity in the scattered light-reduced maximum energization individual light distribution;
determining the threshold light intensity taking into account the maximum light intensity and the preselected percentage threshold value; and
determining the effectively illuminated, rectangular coordinate region, taking into account the scattered light-reduced maximum energization individual light distribution, the coordinate having the maximum light intensity, and the threshold light intensity.

7. The method according to claim 1, wherein the method additionally comprises, after step d), the following steps:
d1) creating a target coordinates buffer from the target coordinates list, a light intensity buffer from all the light intensity lists, and an individual light source identification buffer from all the individual light source identification lists of the maximum energization data structure (22), wherein the target coordinates buffer contains a number of ZK elements which corresponds to the number of target coordinates entries of the target coordinates list, and the target coordinates buffer comprises a starting point and a length specification for each ZK element; and
d2) storing the target coordinates buffer, the light intensity buffer, and the individual light source identification buffer on the computing unit.

8. The method according to claim 1, wherein the-step e) comprises:
e1) creating a target coordinates buffer from the target coordinates list, a light intensity buffer from all the light intensity lists, and an individual light source identification buffer from all the individual light source identification lists of the maximum energization data structure, wherein the target coordinates buffer contains a number of ZK elements which corresponds to the number of target coordinates entries of the target coordinates list, and the target coordinates buffer comprises a starting point and a length specification for each ZK element; or wherein step e) comprises:
e1′) loading the stored target coordinates buffer, the stored light strength buffer, and the stored individual light source identification buffer on the computing unit;
e2) transmitting the target coordinates buffer, the light intensity buffer , and the individual light source identification buffer to a graphics card of the computing unit;
e3) creating an energization value buffer from the provided relative energization values;
e4) transmitting the energization value buffer to the graphics card of the computing unit; and
e5) determining the total light distribution by means of the graphics card of the computing unit, taking into account the target coordinates buffer, the light intensity buffer, the individual light source identification buffer, and the energization value buffer (44).

9. The method according to claim 8, wherein, in step e5), a computer shader having shading units is used, wherein each shader unit processes one ZK element in isolation, and/or wherein the execution strings of the computer shader run in parallel on several shader units of the graphics card.

10. The method according to claim 1, wherein the maximum energization individual light distribution provided in step b) represents an item of color information of the individual light source per coordinate, in addition to the light intensity of the individual light source per coordinate, and the light-intensity list of the maximum energization data structure comprises a combined light intensity-color information entry.

11. The method according to claim 1, wherein
a one-time performance of steps a) through c) is followed by repeated, successive performance of steps d) and e).

12. The method according to claim 11, wherein the pixel headlamp comprises more than 200 individual light sources.

13. The method according to claim 11, wherein the method is for simulating a total light distribution of a pixel headlamp in a night journey of a virtual motor vehicle.

14. The method according to claim 8, wherein a one-time performance of steps a) through c) is followed by a one-time performance of steps e1) or a one-time performance of steps e1′) and e2), and repeated, successive performances of steps e3) through e5).

15. A non-transitory computer-readable medium having processor-executable instructions for determining a total light distribution of a pixel headlamp via a computing unit, wherein the pixel headlamp comprises a plurality of individual light sources, and wherein a light intensity of a respective individual light source can be influenced by energization of the respective individual light source, and wherein the processor-executable instructions, when executed, facilitate:
a) providing a texture on the computing unit comprising a two-dimension array having coordinates;
b) providing a maximum energization individual light distribution for each individual light source on the computing unit, wherein the maximum energization individual light distribution represents at least the light intensity of the individual light source per coordinate at maximum energization of the individual light source;
c) determining a maximum energization data structure taking into account all the maximum energization individual light distributions and the texture, wherein the maximum energization data structure comprises a target coordinates list having target coordinates entries, one light intensity list per target coordinates entry having at least one light intensity entry, and one individual light source identification list per target coordinates entry having at least one identification entry, and wherein the maximum energization data structure at least represents which individual light sources influence the light intensity per coordinate of the texture, and to what extent, at maximum energization;
d) providing a relative energization value for each individual light source on the computing unit, wherein the relative energization value represents the energization of the individual light source; and
e) determining the total light distribution, taking into account the maximum energization data structure and the relative energization values of the individual light sources.
